(19) United States
(12) Patent Application Publication
(10) Pub. No.: US 2024/0092633 A1
(43) Pub. Date: Mar. 21, 2024

(54) MEMS, METHOD OF MANUFACTURING AN MEMS AND METHOD OF CONFIGURING AN MEMS

(71) Applicant: Fraunhofer-Gesellschaft zur Förderung der angewandten Forschung e.V., München (DE)

(72) Inventors: Anton MELNIKOV, Dresden (DE); Jörg AMELUNG, Dresden (DE); Bert KAISER, Dresden (DE); Michael STOLZ, Dresden (DE)

(21) Appl. No.: 18/466,895

(22) Filed: Sep. 14, 2023

(30) Foreign Application Priority Data
Sep. 15, 2022 (DE) 10 2022 209 706.8

(51) Int. Cl. B81B 7/00

(52) U.S. Cl. CPC B81B 7/0061; B81B 2201/0257; B81B 2201/058; B81B 2203/0127; B81B 2207/01; B81B 2207/053; B81B 2207/056

(57) ABSTRACT

An MEMS has a substrate and a cavity arranged in the substrate. A movable element is arranged in the cavity, configured to interact with a fluid arranged in the cavity, wherein a movement of the fluid and a movement of the movable element are causally related. A first opening which connects the cavity to an environment of the substrate causes a first phase offset of a first periodic oscillation which is causally related to the movement of the movable element when passing through the first opening. A second opening which connects the cavity to the environment of the substrate causes a second phase offset, different from the first phase offset, of a second periodic oscillation which is causally related to the movement of the movable element when passing through the second opening.

### CROSS-REFERENCE TO RELATED APPLICATION

This application claims priority from German Application No. 10 2022 209 706.8, which was filed on Sep. 15, 2022, and is incorporated herein by reference in its entirety.

### TECHNICAL FIELD

The present invention relates to an MEMS for producing periodic oscillations in a fluid, potentially an acoustic wave, to an array having several MEMS, to an apparatus having an MEMS, or array, as described herein, and to a method configured for manufacturing an MEMS and/or configuring an MEMS. In particular, the present invention relates to phase-offset air openings.

### BACKGROUND OF THE INVENTION

MEMS-based sound transducers or ultrasonic transducers are an alternative to piezo-based and electrodynamic transducers in many applications. By means of lateral movement of the micro beams in the chip, sound waves can be produced which, by means of suitable sound guiding, are guided to the outside so that there is no acoustic short-circuiting and the acoustic energy can be made use of. Thus, a positive and a negative side can be differentiated between, which are offset by 180°, thereby forming a dipole radiation characteristic for emission. The energy of the back side of the transducer is usually not made use of and dissipated to a closed back volume. However, due to the back volume, additional energy must be used for compressing the air in the closed volume. Furthermore, the back volume uses an installation space which is larger by multiples than the size of the transducer itself.

Consequently, efficient MEMS of small size for providing periodic oscillations in a fluid would be desirable.

### SUMMARY

According to an embodiment, an MEMS may have: a substrate; a cavity arranged in the substrate; at least one movable element arranged in the cavity, configured to interact with a fluid arranged in the cavity, wherein a movement of the fluid and a movement of the movable element are causally related; a first opening which connects the cavity to an environment of the substrate and which causes a first phase offset of a first periodic oscillation which is causally related to the movement of the movable element when passing through the first opening; a second opening which connects the cavity to the environment of the substrate and which causes a second phase offset, different from the first phase offset, of a second periodic oscillation which is causally related to the movement of the movable element when passing through the second opening.

Another embodiment may have an array having a plurality of inventive MEMS as mentioned above.

According to another embodiment, an apparatus may have: an inventive MEMS as mentioned above; or an array having a plurality of inventive MEMS as mentioned above, wherein the first opening and the second opening of the MEMS are connected to the same fluidic volume.

According to another embodiment, a method of producing an MEMS may have the steps of: providing a substrate having a cavity arranged in the substrate; arranging at least one movable element in the cavity so that the movable element is configured to interact with a fluid arranged in the cavity so that a movement of the fluid and a movement of the movable element are causally related; providing a first opening which connects the cavity to an environment of the substrate so that the first opening causes a first phase offset of a first periodic oscillation which is causally related to the movement of the movable element when passing through the first opening; and providing a second opening which connects the cavity to the environment of the substrate so that the second opening causes a second phase offset, which is different from the first phase offset, of a second periodic oscillation which is causally related to the movement of the movable element when passing through the second opening.

According to another embodiment, a method of configuring an inventive MEMS as mentioned above may have the steps of: determining a first characteristic of the first opening for obtaining the first phase offset and determining a second characteristic of the second opening for obtaining the second phase offset based on a predetermined phase relation between the first phase offset and the second phase offset; and manufacturing the MEMS having the first and the second characteristic.

A core idea of the present invention is having recognized that using the energy of periodic oscillation, which in other cases is radiated to the back volume, can be made use of, even with a phase offset relative to other periodic oscillations and, thus, the energy loss caused by dissipating the acoustic energy to the back volume, for compressing the fluid in the back volume, and additionally, the installation space for the back volume can be reduced or even be saved completely, resulting in an MEMS which can, relative to the active side, be constructed with a comparably smaller size and in which installation space, like for the back volume, can be saved. This results in obtaining efficient MEMS of small size.

In accordance with an embodiment, an MEMS comprises a substrate and a cavity arranged in the substrate. A moveable element is arranged in the cavity, configured to interact with a fluid arranged in the cavity, wherein movement of the fluid and movement of the moveable element are causally related. The MEMS comprises a first opening which connects the cavity to an environment of the substrate and is configured to cause a first phase offset of a first periodic oscillation causally related to the movement of the moveable element when passing through the first opening. The MEMS comprises a second opening which connects the cavity to the environment of the substrate and is configured to cause a second phase offset, different from the first phase offset, of a second periodic oscillation causally related to the movement of the moveable element when passing through the second opening. By using the different phase offsets, mutual cancellation of both periodic oscillations in the environment can be reduced or avoided and, thus, both energy contributions can be made useable, thereby allowing MEMS of small size and energy-efficient MEMS.

In accordance with an embodiment, the moveable element is arranged to be moveable in-plane in a plane in parallel to a substrate plane of the substrate. The in-plane actuator system allows efficient generation of periodic oscillations.

In accordance with an embodiment, the MEMS is configured to provide the first phase offset and the second phase offset based on a thermo-viscous effect. It is of advantage here that such an effect can be generated without any problems in an MEMS.

In accordance with an embodiment, the first opening differs from the second opening in at least one among an opening cross-section of the opening; a shape of the opening cross-section along a direction through the substrate; and a depth in the substrate in order to generate the mutually different phase offsets. These differences may be static or dynamic, for example by using actuator technology, thereby offering additional ways of adjusting.

In accordance with an embodiment, the first opening and the second opening are configured to output the first periodic oscillation which comprises the first phase offset, and the second periodic oscillation which comprises the second phase offset, to a common volume in which the first periodic oscillation and the second periodic oscillation superimpose each other. The corresponding energy contributions can be added up there, which allows highly efficient production of periodic oscillations.

In accordance with an embodiment, when superimposing the first periodic oscillation and the second periodic oscillation, in particular in the common volume, an acoustic short-circuiting is avoided and superpositioning is free from any acoustic short-circuiting. Avoiding acoustic short-circuiting in this way allows avoiding or saving back volume of loudspeaker configuration.

In accordance with an embodiment, the first opening and the second opening are arranged on a same side of the substrate, allowing direct emission into a common volume.

In accordance with an embodiment, the moveable element comprises a first side and an opposite second side. The moveable element is configured to generate or trigger the first periodic oscillation with a displacement or shifting or movement of the fluid with the first side, associated with moving the moveable element, and move the fluid through the first opening. In the case of a displacement, shifting or movement of the fluid with the second side, associated with the movement of the moveable element, the second periodic oscillation is generated or triggered and the fluid is moved through the second opening. Here, in particular when periodically driving the moveable element, like so as to resonate, an equal frequency of the first periodic oscillation and the second periodic oscillation can be produced, which can easily be separated, for example, by the different phase offsets and can superimpose each other at the common frequency.

In accordance with an embodiment, sound guiding by the first side through the first opening is different a sound guiding by the second side through the second opening, based on the first phase offset and the second phase offset, thereby avoiding acoustic short-circuiting in a particularly efficient way.

In accordance with an embodiment, the first phase offset exhibits a first correlation to the movement of the moveable element and the second phase offset exhibits a second correlation to the movement of the moveable element. The first phase offset and the second phase offset are mutually related so as to output the first periodic oscillation with the first phase offset and the second periodic oscillation with the second phase offset to the environment with phase matching within a tolerance range. This allows high efficiency of the superimposed oscillations.

In accordance with an alternative embodiment, the first phase offset comprises a first correlation to the movement of the moveable element and the second phase offset comprises a second correlation to the movement of the moveable element. The first phase offset and the second phase offset are mutually related to output the first periodic oscillation with the first phase offset and the second periodic oscillation with the second phase offset to the environment with a directional characteristic obtained by superimposing the first periodic oscillation and the second periodic oscillation. This allows maintaining a certain, maybe small phase offset at the location of superpositioning so that the phase offset can be made use of as an obtained directional characteristic. This allows additional degrees of freedom when using the MEMS.

In accordance with an embodiment, the directional characteristic is arranged obliquely relative to a surface normal of the substrate and a direction of the first opening and/or the second opening.

In accordance with an embodiment, the MEMS comprises a phase matcher configured to receive a drive signal and to match (or adjust) the first phase offset and/or the second phase offset based on the drive signal. This allows high variability when operating the MEMS.

In accordance with an embodiment, the phase matcher is configured to change a size of the first opening, to adjust the first phase offset and/or to change a size of the second offset to adjust the second phase offset. Although the embodiments described herein do not exclude adjusting the phase offset by using thermal energy for locally heating and/or cooling, and/or to adjust the phase delay in at least one of the openings by means of locally increasing pressure, adjusting a size of the opening offers an easy way of adjusting the phase offset.

In accordance with an embodiment, an array comprises a plurality of MEMS as described herein which may be formed to be equal or different. This allows generating strong signals of a special frequency and/or generating periodic oscillations over a broad band.

In accordance with an embodiment, the array is configured to emit the first phase-offset periodic oscillations with a common directional characteristic and/or emit the second periodic oscillations with a common directional characteristic. This allows an efficient usage of the MEMS.

In accordance with an embodiment, the array is configured to emit the first phase-offset periodic oscillations with a common directional characteristic, which, relative to a surface normal of the substrate and a direction of the first openings of the plurality of MEMS, is arranged obliquely and in which the first openings of the plurality of MEMS are implemented for a mutually different phase offset. Alternatively or additionally, the array is configured to emit the second phase-offset periodic oscillations with a common directional characteristic which, relative to a surface normal of the substrate and a direction of the second openings of the plurality of MEMS, is arranged obliquely and in which the second openings of the plurality of MEMS are implemented for a mutually different phase offset. Since the different openings which contribute to a common directional characteristic, are arranged at different locations, these local differences can be compensated by correspondingly adjusting the phase shift or phase offsets, in analogy to an antenna array in which locally differently positioned antennas can nevertheless contribute to a common directional characteristic of a radio wave.

In accordance with an embodiment, an array is provided in which the plurality of first openings provide a respective phase offset of the first periodic oscillations and superpositioning of the phase-offset first periodic oscillations is directed onto a common first focus region. Alternatively or additionally, the plurality of second openings provide a respective phase offset of the second periodic oscillations and superpositioning of phase-offset second periodic oscillations is directed onto a common second focus region.

In accordance with an embodiment, the first focus region and the second focus region are spatially adjacent to each other or overlapping, which may result in an enlargement of the focus region relative to a single focus region or may result in an amplification of the periodic oscillation in the overlapping focus region.

In accordance with an embodiment, the array comprises a controller configured to provide a match signal. The array comprises a phase matcher configured to receive the drive signal and to match at least a first offset of at least one of the first openings and/or at least one second phase offset of at least one of the second openings based on the drive signal. This allows varying an output signal obtained by the array.

In accordance with an embodiment, the controller is configured to control the phase offset of the at least one second opening irrespective of a phase offset of the at least one first opening and/or to control the phase offset of the at least one first opening irrespective of a phase offset of the at least one second opening. This allows high precision when driving the array.

In accordance with an embodiment, the controller is configured to control the phase matcher based on the drive signal to produce, for superpositioning of the phase-offset first periodic oscillations and/or for superpositioning of the phase-offset second periodic oscillations, at least one among a change in a lobe of a directional characteristic of superpositioning; compensation for broad-band matching; and modulation of a signal to a frequency of the first and/or second phase-offset periodic oscillations.

In accordance with an embodiment, an apparatus is provided, comprising at least one MEMS or array while matching the embodiments described herein. The first opening and the second opening of the MEMS are connected to the same fluidic volume.

In accordance with an embodiment, the MEMS is configured to be a loudspeaker and is configured not to comprise a back volume.

In accordance with an embodiment, a method for manufacturing an MEMS comprises providing a substrate having a cavity arranged in the substrate, and arranging a movable element in the cavity so that the movable element is configured to interact with a fluid arranged in the cavity so that a movement of the fluid and a movement of the movable element are causally related. The method comprises providing a first opening which connects the cavity to an environment of the substrate so that the first opening causes a first phase offset of a first periodic oscillation which is causally related to the movement of the movable element, when passing through the first opening, and providing a second opening which connects the cavity to the environment of the substrate so that the second opening causes a second offset, which is different from the first phase offset, of a second periodic oscillation causally related to the movement of the movable element, when passing through the second wave.

In accordance with an embodiment, a method for configuring an MEMS comprises determining a first characteristic of a first opening in a substrate for obtaining the first phase offset, and a second characteristic of the second opening for obtaining the second phase offset based on a predetermined phase relation between the first phase offset and the second phase offset. Additionally, the method comprises manufacturing the MEMS having the first characteristic and the second characteristic.

### BRIEF DESCRIPTION OF THE DRAWINGS

Embodiments of the present invention will be detailed below referring to the appended drawings, in which:

FIG. 1a shows a schematic side sectional view of an MEMS in accordance with an embodiment having an in-plane movable element;

FIG. 1b shows a schematic side sectional view of an MEMS in accordance with an embodiment with an out-of-plane movable element;

FIG. 2 shows a schematic side sectional view of an MEMS in accordance with an embodiment in which the substrate is formed to have several layers;

FIG. 3 shows a schematic block circuit diagram of an MEMS in accordance with an embodiment in which a cavity is subdivided into a total of three sub-cavities by two movable elements;

FIG. 4 shows a schematic side sectional view of an MEMS in accordance with an embodiment in which openings of the cavity are arranged on a same side of the substrate;

FIG. 5 shows a schematic side sectional view of an array in accordance with an embodiment;

FIG. 6a shows a schematic side sectional view of an array in accordance with an embodiment in which the arranged MEMS are formed to be mutually different;

FIG. 6b shows a schematic side sectional view of an array in accordance with an embodiment in which mutually deviating directions of propagation of the MEMS regions can be obtained by configuring the respective phase shifts;

FIG. 6c shows a schematic side sectional view of an array in accordance with an embodiment in which the respective second openings of the MEMS are oriented towards different spatial directions;

FIG. 7 shows a schematic side sectional view of an array in accordance with an embodiment in which the first openings on the one hand and the second openings on the other hand are arranged at opposite sides of the respective MEMS;

FIGS. 8a-c show schematic side sectional views of MEMS in accordance with embodiments described herein for discussing phase matching obtained by the respective opening;

FIG. 9a shows a schematic side sectional view of an MEMS in accordance with an embodiment which, compared to the MEMS from FIG. 2, comprises a phase matcher;

FIG. 9b shows a schematic side sectional view of an MEMS in accordance with an embodiment which, compared to the MEMS from FIG. 4, was extended by providing phase matchers;

FIG. 10 shows a schematic flow chart of a method in accordance with an embodiment which may be used, for example, for producing an MEMS as described herein; and

FIG. 11 shows a schematic flow chart of a method in accordance with an embodiment which may, for example, be used for configuring or dimensioning an MEMS as described herein.

### DETAILED DESCRIPTION OF THE INVENTION

Before discussing embodiments of the present invention in greater detail below while referring to the drawings, it is pointed out that identical elements, objects and/or structures or those of identical function or identical effect are provided with same reference numerals in the different figures, so that the description of these elements illustrated in different embodiments is mutually exchangeable or mutually applicable.

Embodiments described below will be described in the context of a plurality of details. However, embodiments may also be implemented without these detailed features. Furthermore, for the sake of understandability, embodiments will be described while using block circuit diagrams, to replace a detailed illustration. Additionally, details and/or features of individual embodiments may easily be combined with one another, unless the opposite is described explicitly.

The following embodiments relate to micromechanical devices (MEMS devices). The devices described herein may comprise multi-layered layer structures, wherein different functions may be implemented in different layers, for example mechanical movement, conducting electrical signals and/or force generation. However, this does not exclude combining different functions in the same layer of the MEMS, like an electrical signal, force generation or movement, or parts thereof.

MEMS may, for example, be obtained by processing semiconductor materials, like on the wafer level, which may also comprise combining several wafers and/or depositing layers on the waver planes. Some of the embodiments described herein relate to MEMS planes. An MEMS plane is not necessarily to be understood to be a two-dimensional or unbent plane which may basically extend in parallel to a processed wafer, like in parallel to a main side of the wafer or the future MEMS. A plane direction of such a plane or layer plane may be understood to be a direction within this plane, which may also be referred to by “in-plane”. A direction perpendicular to this, that is perpendicular to a plane direction, may easily also be referred to as thickness direction or layering direction, wherein the term thickness does not mean any limitation in the sense of an orientation of this direction in space. Alternatively or additionally, the term “out-of-plane” may also be used.

It is to be understood, that terms used herein, like “length”, “width”, “height”, “top”, “bottom”, “left”, “right” and the like are used only for illustrating embodiments described herein, which do not restrict the invention since the respective positioning of an element in space may be varied as desired and the embodiments may consequently also be positioned in different orientations.

Some of the embodiments described herein are described in the context of producing periodic oscillations in a fluid, like sound waves, ultrasonic waves, acoustic waves or the like. Such implementations, however, do not exclude a complementary implementation as a sensor for a sensor evaluation using the MEMS device, like in analogy to a microphone function of the MEMS or the like. Embodiments relate to making easily usable a movement of a movable element in a cavity by different phase offsets in openings between the cavity and the environment. It is to be understood that such a phase offset can also be employed easily in the case of sensor evaluation.

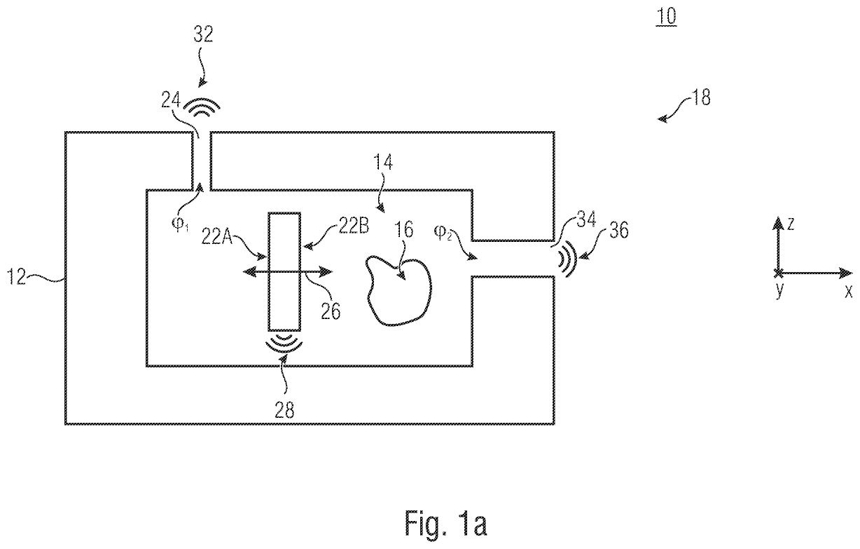

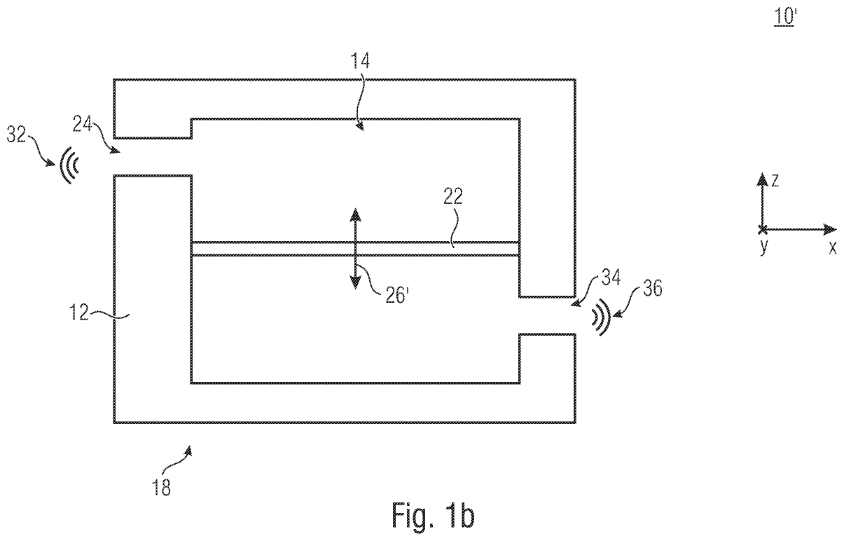

FIG. 1a shows a schematic side sectional view of an MEMS 10 in accordance with an embodiment. The MEMS comprises a substrate 12 and a cavity 14 arranged in the substrate 12. A fluid 16 can be arranged in the cavity, which may exemplarily comprise a composition matching an environment 18 of the MEMS, like air, or a different composition according to the environment 18.

The substrate may be formed to be single-layered or multi-layered and may exemplarily comprise a semiconductor material, like silicon or a silicon-based material, different semiconductor materials or a combination thereof. Alternatively or additionally, the substrate 12 may in principle also be formed differently, wherein at least a sub-region or a layer may potentially comprise electrically conductive materials, like for conducting electrical power or information signals.

The MEMS 10 comprises a movable element 22 arranged in the cavity 14. The movable element 22 is configured to interact with the fluid 16. A movement of the fluid 16 and a movement of the movable element 22 are causally related. This means that a potentially electrically or thermally driven movement of the movable element 22 may result in a movement of the fluid 16 and/or that a movement of the fluid 16, for example due to a difference in pressure or variation in pressure in the environment 18, may cause a movement of the movable element 22.

The MEMS comprises a first opening 24 in the substrate which connects the cavity to the environment 18 of the substrate 12. When passing through the first opening 24, a pressure wave, oscillation or periodic oscillation produced in the fluid 16 may be subjected to a phase shift or phase offset. The periodic oscillation may be referred to as wave or soundwave. A frequency range may be in the audible range, but may also be arranged outside it, for example in an ultrasonic or infrasonic range. Consequently, the term acoustic wave is not limiting in the context with the embodiments described here, but only exemplary when referring to the frequency range.

For example, a periodic oscillation 28 can be generated in the cavity 14 based on a movement of the movable element 22 along a direction of movement 26, which may, for example, be arranged in-plane along the positive and negative x directions. It may be subjected to a phase offset when passing through the opening 24 and be emitted to the environment 18 as a phase-offset oscillation 32.

The MEMS 10 comprises a second opening 34 in the substrate 12, which also connects the cavity 14 to the environment 18 of the substrate 12. The opening 34 also provides a phase offset for the periodic oscillation 28 so that a second phase-offset oscillation 36 can be emitted by the MEMS 10 from the opening 34 to the environment 18. The phase offset caused by the opening 24 is thus different from the phase offset caused by the opening 34.

The periodic oscillation 28 provided by the movable element 22 here is only illustrated as an example of a common periodic oscillation. This is easily possible based on an arrangement or positioning of the respective openings 24 and 34. Alternatively, the movable element 22 can subdivide the cavity 14 into at least two sub-cavities and a periodic oscillation generated in each of the sub-cavities may form a basis for the respective phase-offset oscillation 32 and 36. For example, an implementation can be obtained in which the movable element can comprise a first side 22A and an opposite second side 22B. The movable element 22 can be configured to produce the periodic oscillation 32 when displacing the fluid 16 with the first side 22A, associated with the movement of the movable element 22, and move the fluid through the opening 24. With a movement of the movable element 22 and an associated displacement of the fluid 16 with the side 22B, the periodic oscillation 36 can be generated and the fluid be moved through the opening 34. The different sides 22A and 22B can be understood to be phase-different sides of the radiating movable element 22.

In accordance with an embodiment, sound guiding through the opening 24 with the side 22A may be different from the sound guiding through the opening 34 with the side 22B, based on the mutually different phase offsets.

In accordance with other embodiments, it is also easily possible to provide the openings 24 and 34 with an oscillation caused or produced by the same side 22A or 22B, while using different phase delays.

The movable element 22 may comprise an active structure or a passive structure, Thus, the movable element 22 may, for example, comprise a plate structure or a beam structure or the like, which may be formed to be rigid or elastic, and which may be coupled to an actuator so as to move the structure. Electrostatic, electrodynamic, piezoelectric or thermal actuators, for example, are suitable for this.

However, it is also easily possible to form the movable element 22 itself as an active structure. Exemplarily, two or more essentially parallel beam structures may be arranged, which are fixedly connected to one another at discrete regions. For example, in one implementation as an electrode structure, the movement of the movable element 22 can be obtained by applying an electrical potential, like by deforming the movable element 22.

The phase offset of the opening 24 and the phase offset of the opening 34 may, for example, be provided based on a thermoviscous effect, for example by pressing the fluid 16 through the narrowed region and, thus, triggering the thermoviscous effect. In order to produce different degrees of the phase offset, the openings 24 and 34 may thus differ in at least one among an opening cross-section of the opening, a shape of the opening cross-section along a direction through the substrate and a depth in the substrate.

FIG. 1b shows a schematic side sectional view of an MEMS 10′ in accordance with an embodiment. Compared to the MEMS 10, the movable element 22 is, for example, formed as a membrane structure suspended along the plane directions x/y, wherein a different implementation may also be realized, which allows a deflection along a deflection direction 26′, for example in parallel to the z direction, which, in accordance with an embodiment, is out of plane.

The MEMS 10′ may also provide phase-offset periodic oscillations 32 and 36 based on the movement of the movable element 22, as does the MEMS 10, which are obtained, for example, due to different phase offset contributions through the openings 24 and 34.

In the embodiment of FIG. 1b, the openings 24 and 34 are arranged on phase-different sides of the movable element 22, wherein the openings 24 and 34 may also be arranged on the same side.

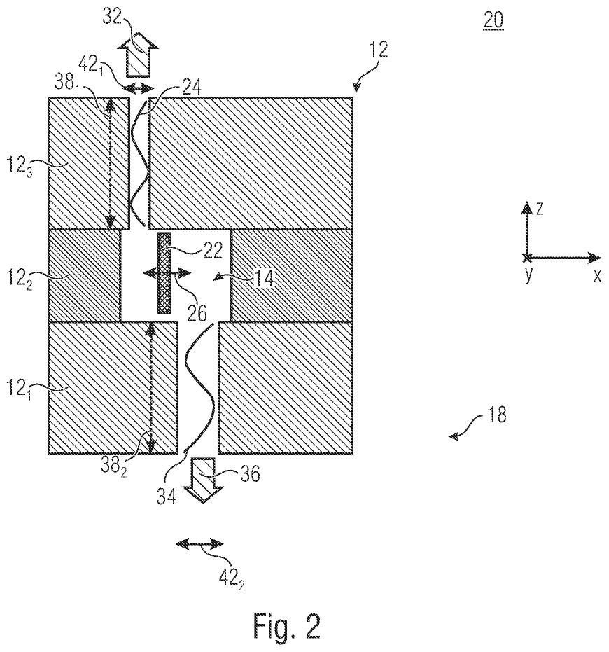

FIG. 2 shows a schematic side sectional view of an MEMS 20 in accordance with an embodiment. The substrate is, for example, formed in several layers and comprises at least two, in the specific illustration three, layers 12₁, 12₂ and 12₃. The layer 12₁ may, for example, be referred to as bottom wafer, or be formed from it, whereas the layer 12₂ comprising the movable element 22 may be referred to as device wafer. The layer 12₃ may mark off the cavity 14 along the z direction, together with the layer 12₁, so that the layer 12₃ may also be referred to as lid wafer. The openings 24 and 34 are, for example, arranged in the layers 12₃ and 12₁.

The mutually different contributions to the phase offset may, for example, be obtained based on different thicknesses 38₁ and 38₂ in the layers 12₃ and 12₁. This may, for example, simply be obtained by providing the corresponding layers 12₁ and 12₃ in different thicknesses. Alternatively or additionally, it is also possible to locally increase the size of the opening 24 and/or 34 in a region of the cavity 14 or the environment 18 such that, in the enlarged region, there is effectively no contribution to the phase delay, or only a negligible contribution. Alternatively or additionally to different dimensions 38₁ and 38₂ along the z direction, a dimension 42₁ and 42₂ along the x direction and/or y direction may be mutually different, that is a different length or different width or mutually different cross-sectional area may be implemented. Due to the phase offset between the openings or air outlets 24 and 34, like based on different geometries of the air outlets, the directional characteristic of superpositioning the periodic oscillations 32 and 36 can be controlled.

In other words, FIG. 2 shows the cross-section of a wafer stack of three layers with a displacing element or movable element. The displacing element comprises a first and a second displacing side and two differently formed air outlet openings each, terminating at advantageously different, but basically arbitrary chip sides. By selecting the position, the geometrical shape and the width, a phase offset is produced between the exiting waves, which can be made use of for shaping a directional characteristic in the free field. The depth of the air openings along the z direction may, for example, be in a range of at least 1 μm to 1500 μm, advantageously at least 200 μm and at most 800 μm. The width 24₁ and/or 24₂ of the openings 24 and 34 as illustrated may advantageously have a value of at least 1 μm to at most 150 μm and advantageously from at least 10 μm to at most 50 μm, wherein such concepts may be transferred to any other dimensions.

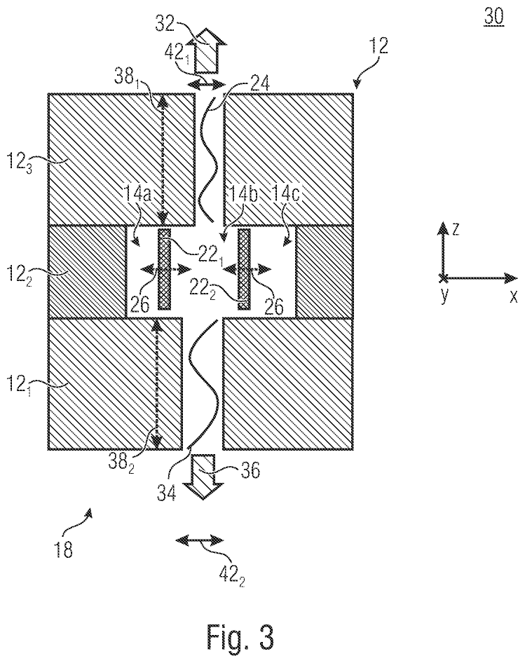

FIG. 3 shows a schematic block circuit diagram of an MEMS 30 in accordance with an embodiment. The cavity 14 is subdivided into a total of three sub-cavities 14a, 14b and 14c by two movable elements 22₁ and 22₂, wherein the number of three sub-cavities and the number of two movable elements are exemplary only. By exciting the movable elements 22₁ and 22₂ in an anti-phase way so that they can move towards each other and away from each other along the x direction, a pressure variation can be increased in the periodic oscillations 32 and 34 when compared to the MEMS 20. At the same time, the MEMS 30, may, while performing additional amendments, allows additional degrees of freedom. Alternatively or additionally to connecting the sub-cavity 14b to the environment 18, for example, the sub-cavity 14a and/or 14c may also be connected to the environment 18. If the movable elements 22₁ and 22₂ are, for example, driven using mutually different frequencies and/or at a phase offset to each other, a spectrum of superpositioning of the periodic oscillations 32 and 36 may be matched.

Like in the MEMS 10 and/or the MEMS 20, an implementation may be made such that the openings 24 and 34 are configured to emit the respective periodic oscillation 32 and 36 to a common volume, that is the environment 18, in which the periodic oscillations 32 and 36 superimpose each other. In a far field of the MEMS 30, there is advantageously no mutual cancellation of the periodic oscillations obtained, that means superpositioning of the periodic oscillations 32 and 36 is free from any acoustic short-circuiting.

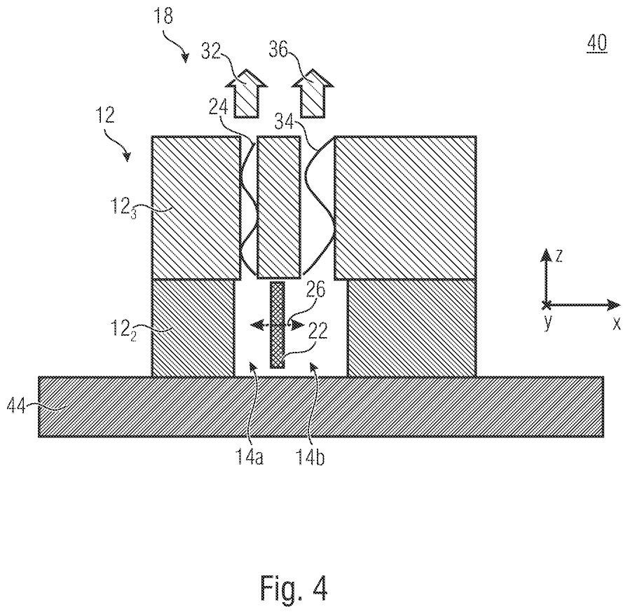

FIG. 4 shows a schematic side sectional view of an MEMS 40 in accordance with an embodiment. In the embodiment of the MEMS 40, the openings 24 and 34 are arranged on a same side of the substrate 12. Thus, exemplarily, the layer 12₃ may comprise the openings 24 and 34 arranged next to each other. In accordance with a possible embodiment, the different phase offsets here may be configured such that the periodic oscillations 32 and 36 are in phase or in phase within a tolerance range. A deviation from being in phase, for example, allows setting a directional characteristic in a direction which is inclined relative to the z-axis.

Exciting the periodic oscillations 32 and 36 may, for example due to the configuration of the movable element 22, be in two periodic oscillations, mutually phase-offset by 180°, in the sub-cavities 14a and 14b. In one configuration of the openings 24 and 34 such that there is again a 180° phase rotation relative to each other, the two periodic oscillations 32 and 34 may again be in phase relative to each other.

Like in the MEMS 10, 10′, 20 and/or 30, in the MEMS 40, too, there may be a mutually different correlation of the movement of the movable element 22 relative to the phase offset provided by the opening 24 and 34. The phase offset provided by the opening 24 and the phase offset provided by the opening 34 may be in a relation to each other which may be configured such that the phase relation between the periodic oscillations 32 and 36 has a predetermined characteristic. In accordance with an embodiment, it can be adjusted such that there is, within a tolerance range, a matching phase of the periodic oscillations 32 and 36 when these are radiated to the environment 18. Alternatively, based on a deviation from a matching phase and, thus, based on the relation between the first phase offset and the second phase offset of the opening 24 and the opening 26, with superpositioning of the periodic oscillations 32 and 36, a directional characteristic can be obtained with which the superpositioning of the periodic oscillations 32 and 36 is emitted to the environment.

When compared to the MEMS 20 and 30, one layer of the substrate 12 may, for example, be formed as a board 44 to mark off the cavity, or sub-cavities 14a and/or 14b, along the negative z-direction. Alternatively, a handling wafer can easily be arranged.

In other words, FIG. 4 shows a wafer stack made of two layers and a displacing element. The displacing element has a first and a second displacing side and two air outlet openings each shaped differently which advantageously terminate at the same chip side. The depths and widths may be comparable to those of the MEMS 20. By selecting the position, the geometrical shape and the width, a phase offset can be generated between the emitted waves, which prevents acoustic short-circuiting at the chip surface, thereby allowing the largest part possible of the energy to be used for generating sound waves, acoustic waves or periodic oscillation of the chip, which is used as a synonym. This allows avoiding a back volume.

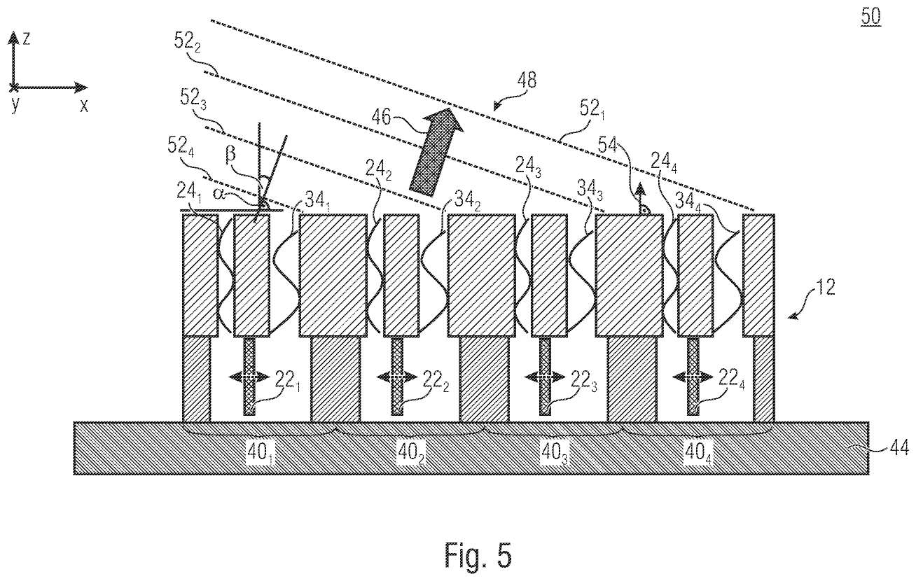

FIG. 5 shows a schematic side sectional view of an array 50 in accordance with an embodiment. The array 50 exemplarily comprises at least two MEMS, like, for example, four 40₁-40₄, wherein alternatively or additionally, other MEMS 10, 10′, 20 and/or 30 may also easily be arranged. An array matching those described in embodiments may comprise at least two, at least three, at least four or a higher number of at least five, at least seven, at least ten or more equal or different MEMS. Exemplarily, but not necessarily, the respective MEMS here are configured such that the phase relation between the openings 24 and 34 is configured so as to obtain an inclined radiation direction 46 which, compared to a surface normal, for example in parallel to the z-direction of the substrate, is inclined by an angle β and/or, relative to the surface of the substrate 12, by an angle α, β≠n·90° with n=1, 2, 3, 4.

A spatial offset of the different MEMS 40₁-40₄ along the z-direction may be considered by a phase-offset excitation of the movable elements 22₁-22₄ so as to obtain the common wave front 48 obtained which can be characterized by a wave front or several lines 52₁-52₄ of equal phase. Alternatively or additionally, such a phase relation may also be obtained by a mutually different implementation of the respective openings 24₁-24₄ and 34₁-34₄ relative to one another.

The array 50 may be configured with both variations, but also in a combinatorial manner to radiate the phase-offset oscillations 32 and the phase-offset oscillations 36 of the MEMS 40₁-40₄ at a common directional characteristic. Here, the directional characteristics 32 may be mutually matched and/or the directional characteristics 34 may be mutually matched.

In other words, FIG. 5 shows an extension of the arrangement of FIG. 4, where the air outlet openings arranged on one side additionally perform the function of an array. The phase offset here is selected to be such that the forming wave front is not in parallel to the chip surface. Thus, the transducer exhibits a marked main lobe which is not oriented to be perpendicular to the chip surface. Here, the angle is also limited by the Bragg condition and, consequently can be determined at least partly by the periodicity of the displacing elements 22₁-22₄ and the free-field wave length.

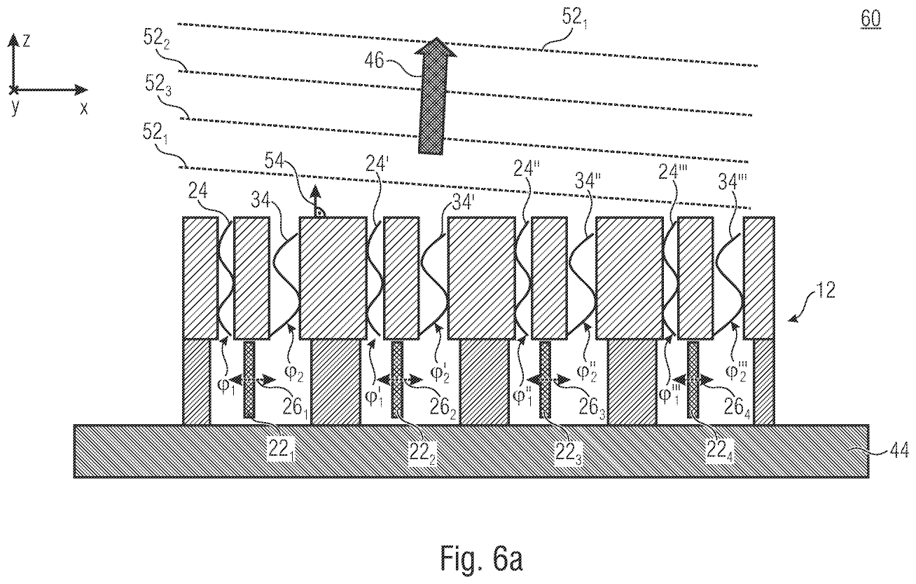

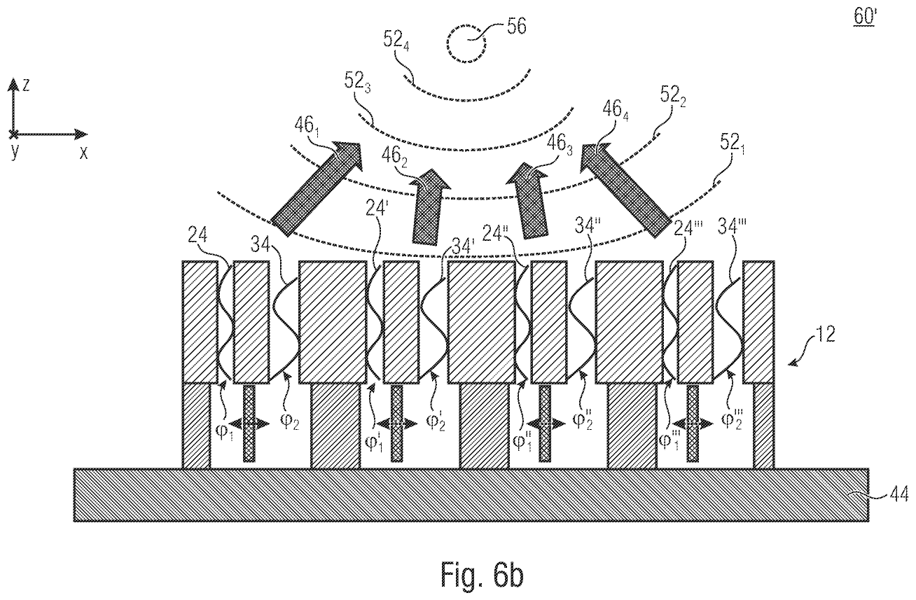

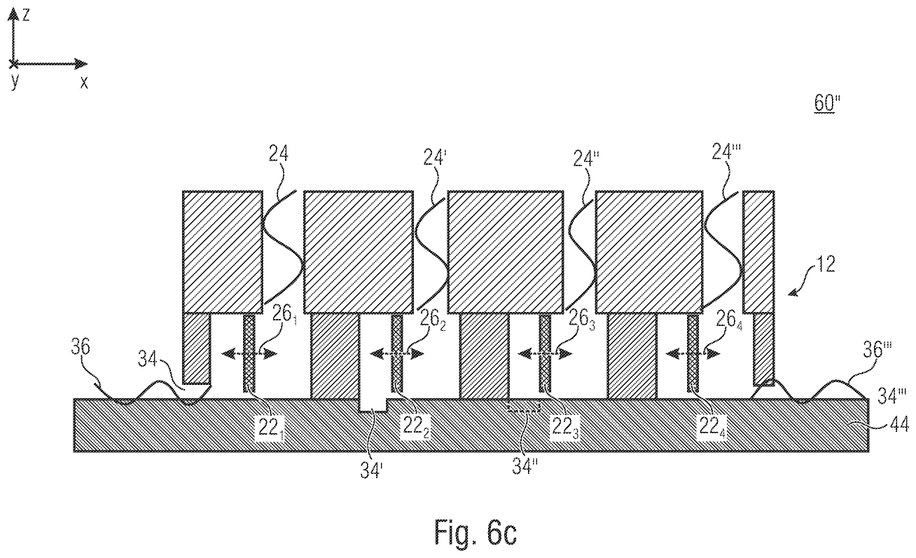

FIG. 6a shows a schematic side sectional view of an array 60 in accordance with an embodiment, wherein the arranged MEMS are formed to be mutually different such that a phase offsets φ₁, φ_{1′}, φ_{1″} and φ_{1′″} of different MEMS are different. Such an array may also be referred to as an MEMS array. Alternatively or additionally to the mutually different phase offsets, phase offsets φ₂, φ_{2′}, φ_{2″} and φ_{2′″} may be mutually different to obtain the emission direction 46 which is inclined relative to the surface normal 54. Thus, a phase difference φ₂−φ₁ or φ_{2′}−φ_{1′} and/or φ_{2″}−φ_{1″} and/or φ_{2′″}−φ_{1′″} of the different MEMS may be identical, at least approximately.

In accordance with an embodiment shown in FIG. 6a, the array is configured to emit the phase-offset periodic oscillations 32 of the MEMS 40₁-40₄ at a common directional characteristic which, relative to the surface normal 54 of the substrate 12 and a direction of the openings 24, here, for example, the z-direction, is arranged to be oblique and in which the openings 24₁-24₄ are implemented for a mutually different phase offset. Alternatively or additionally, an array as described here, like the array 50, may be configured to emit the phase-offset periodic oscillations 36, which pass through the openings 34₁-34₄, at a common directional characteristic which, relative to the surface normal 54 and a direction of the openings 34₁-34₄, like the z-direction, is arranged obliquely. Here, the openings 34₁-34₄ may be implemented for a mutually different phase offset.

In other words, FIG. 6a shows an extension of the arrangement of FIG. 5 where the air exit openings are subdivided into further groups, in accordance with the MEMS 40₁, the MEMS 40₂, the MEMS 40₃ and the MEMS 40₄, which are additionally mutually different in their geometrical dimensions and/or the shape. This allows realizing an additional phase offset of the wave outlet between the individual displacing elements. This setup allows overcoming the limits of the Bragg condition and designing main lobes the angles of which are independent on the periodicity of the displacing elements.

FIG. 6b shows a schematic side sectional view of an array 60′ for which the explanation of MEMS 60 apply largely. Different from the array 60, the array 60′ may be implemented such that while configuring the respective phase shifts φ₁−φ_{2′″}, mutually deviating propagation directions 461-464 of the MEMS regions can be obtained. Superpositioning of the respective periodic oscillations may result in at least approximately curved wave fronts 52₁-52₄, unlike the array 60. The array 60′ can be configured to direct or focus the emitted periodic oscillations onto a common focus region 56. Alternatively, groups of MEMS components or MEMS regions or individual MEMS may be used to focus onto a respective focus region 56 so that several spatially disjoint or overlapping focus regions may be provided with the periodic oscillations.

This means that the plurality of openings 24 which can provide a respective phase offset of the periodic oscillations passing through the same, can direct the emitted waves or periodic oscillations onto a common focus region 56, at least in groups. Alternatively or additionally, the openings 34, 34′, 34″ and 34′″ may also direct these onto an also common focus region, based on superpositioning of phase-offset periodic oscillations. By matching the openings 24-24′″ for example, a first focus region can be generated, and a second focus region can be generated by matching the openings 34-34′″. These focus regions may overlap, be mutually adjacent so as to cause an increase of the overall focus region, or may be spatially disjoint.

FIG. 6c shows a schematic side sectional view of an array 60″ in accordance with an embodiment. Here, the respective second openings 34, 34′, 34″ and 34′″ are oriented relative to different spatial directions −x, −y, +y, +x. Such a usage of two or more spatial directions for the first openings 24-24′″ on the one hand and 34-34′″ on the other hand, may be performed for any of the openings 24/34 or both and may be configured to be equal or to be mutually different. It is to be pointed out that the movable elements 22₁-22₄ can be driven synchronously to one another, but also differently.

Using a common carrier substrate or board 44 for housing the cavities allows generating one or more of the openings 34, 34′, 34″ or 34′″ by implementing the board 44 in an easy way, for example by introducing grooves, trenches and/or holes. All the openings 34-34″ here can be configured correspondingly, but may also be, as is illustrated, a combination by introducing openings in the semiconductor material of the substrate 12 on the one hand, see openings 34 and 34′″, in combination with processing the board 44, as is illustrated for the openings 34′ and 34″. This means that embodiments also allow setting a phase offset using the setup and connection technique (AVT), maybe using a special carrier board having corresponding trenches, groove, holes and/or glue used. Here, the carrier board may exhibit special adaptations, like the mentioned trenches, grooves and/or holes, and adjusting may be performed per displacing chamber or corresponding cavity. A glue used for connecting chip and carrier board may be used additionally or as an alternative to channel shaping, like as a filling material or for setting a channel height.

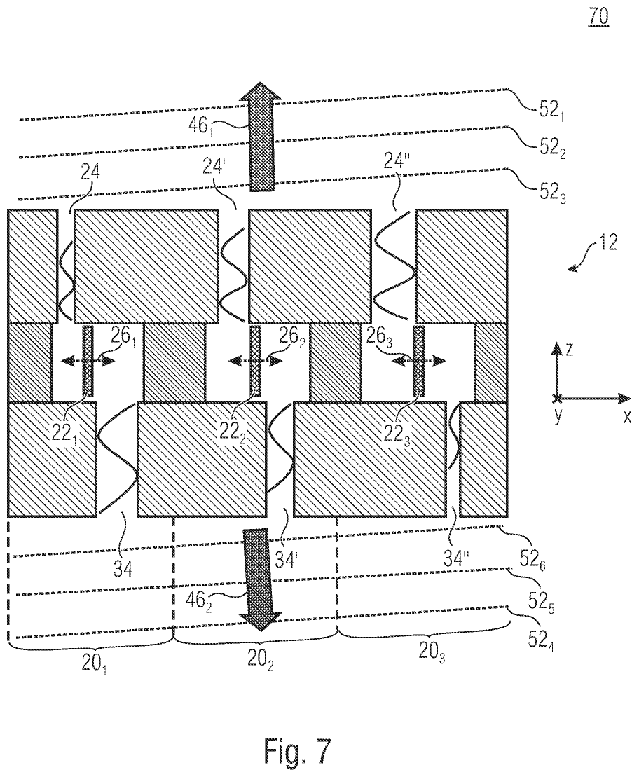

FIG. 7 shows a schematic side sectional view of an array 70 in accordance with an embodiment. When compared to the array 60, the openings 24, 24′ and 24″ on the one hand and 34, 34′ and 34″ on the other hand are arranged on opposite sides of the respective MEMS 20₁, 20₂ and 20₃. As is also the case in other arrays described herein, the individual MEMS structures 20₁, 20₂ and 20₃ may comprise a number different from three, and may be implemented to be mutually equal or mutually different. It is to be understood that the respective MEMS of an array may form individual MEMS elements, but may also be formed to be integrated monolithically.

Even when the two exit sides of the wave fronts 52₁-52₃ on the one hand and 52₄-52₆ on the other hand are illustrated to be mutually opposite, any other, mutually different sides may be chosen, or, as discussed in connection with FIG. 5 or FIG. 6a, the same side.

Using different sides allows making use of the respective advantages on more than one side so that propagation directions 461 and 462 may be set and implemented independently.

In other words, FIG. 7 shows a combination of the explanations of FIG. 2 and FIG. 6a where the air exit openings are located on different chip sides and differ in their geometry and, maybe, position. Thus, both chip sides are implemented to be an array configuration, wherein the angles of the two main lobes may be designed independently.

While the arrays 60 and 60′ show a propagation direction 46 which is oblique relative to the surface normal of the substrate and/or the direction of the respective openings 24/34, such an oblique implementation on both sides of the chip can be obtained by corresponding openings, as is shown, for example, for the array 70. Such an oblique implementation, however, is not restricted to arrays to MEMS as described herein, but may also be obtained already by an individual MEMS, for example by providing two or more openings on one chip side, the phase matching of which is mutually adjusted, like an individual MEMS 40.

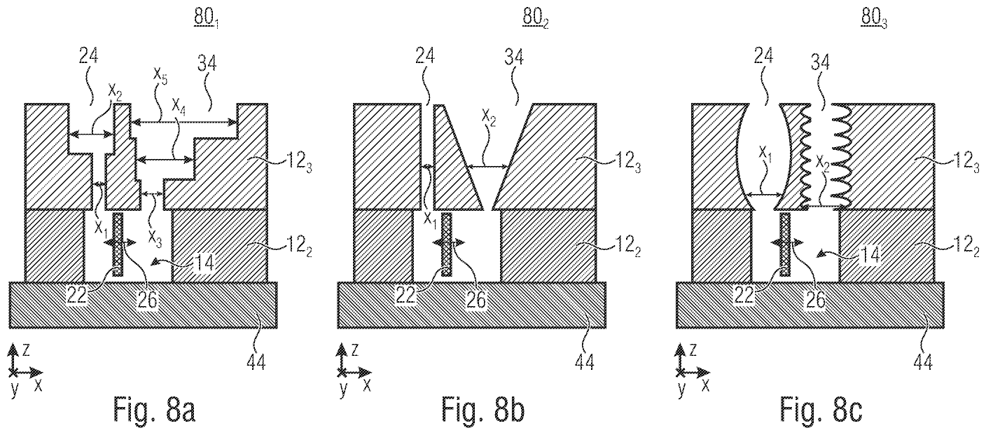

FIGS. 8a, 8b and 8c show schematic side sectional views of MEMS 80₁, 80₂ and 80₃ in accordance with embodiments described herein, which may be implemented individually or as an array, wherein combinations of different MEMS in an array are easily possibly. Phase matching of the openings 24 and/or 34 is described making reference to FIGS. 8a, 8b and 8c. For setting a respective phase offset, a variation of the shape of the openings 24 and/or 34 may be implemented possibly. Possibly, these may be formed along the wave propagation direction. Exemplarily, in FIG. 8a, a discontinuous, step adjustment of a size x₁, x₂ of the opening 24 along the z-direction is, for example, shown for the opening 24. It may, for example in the layer 12₃, vary between two dimensions which exemplarily increase with an increasing distance from the cavity 14. A step size of two or an implementation of a single discontinuous jump is only exemplary. A high number is also possible, as is, for example, shown for the three different dimensions x₃, x₄ and x₅ for the opening 34 in FIG. 8a.

The dimensions x₃, x₄ and x₅ here also increase with an increasing distance from the cavity 14, but this is not necessarily the case.

It is shown in FIG. 8b that a variation of a dimension x₂ of one of the openings 34 can be implemented, whereas the dimension x₁ of the opening 24, which is not necessarily a smaller opening than the opening 34, may be implemented.

Optionally, for implementing a variable dimension x₂ as a continuous change, the MEMS 802 may also comprise a discontinuous variation, matching that of FIG. 8a with one or more steps. Alternatively or additionally, the MEMS 80₁ may also comprise a continuous variation in the opening 24 or the opening 34 and/or a constant dimension of the opening 24 and/or 34.

FIG. 8c shows that the dimension of the opening 24 and/or 34 may be implemented as desired with an increasing distance along the z-direction, when starting from the cavity 14, and is not restricted to a monotonous or strictly monotonous increase. Thus, the dimension x₁ of the opening 24 decreases again after reaching a local maximum when viewed along the positive z-direction starting from the cavity 14. This may also take place periodically or aperiodically, as is shown, for example, for the opening 34. It is mentioned that a decrease in the MEMS 80₁, 80₂ and/or 80₃ may also take place, instead of an increase in the dimension x₁, when starting from the cavity 14.

This means that another way of setting the phase offset of an MEMS as described herein may be by varying the shape of the air outlet opening in the wave propagation direction. Here, one or several steps may be provided, for example by means of etching. Alternatively or additionally, oblique walls of the opening may be provided as is shown, for example, for the MEMS 80₂. Alternatively or additionally, non-straight walls or non-sloped walls may be provided, for example as so-called scallops or curved walls as is illustrated for the MEMS 80₃.

Although the variable size of the openings 24 and/or 34 is described only along the x-direction, a corresponding implementation may alternatively or additionally also take place along the y-direction, wherein a corresponding size can be set independently.

Whereas a settable and constant phase offset of the openings 24 and/or 34 was described before, embodiments of the present invention also provide for providing a statically or dynamically changeable phase offset. In accordance with an embodiment, an MEMS and/or and array here comprise a phase matcher configured to receive a drive signal to adjust the phase offset of the opening 24 and/or the phase offset of the opening 34 based on the drive signal.

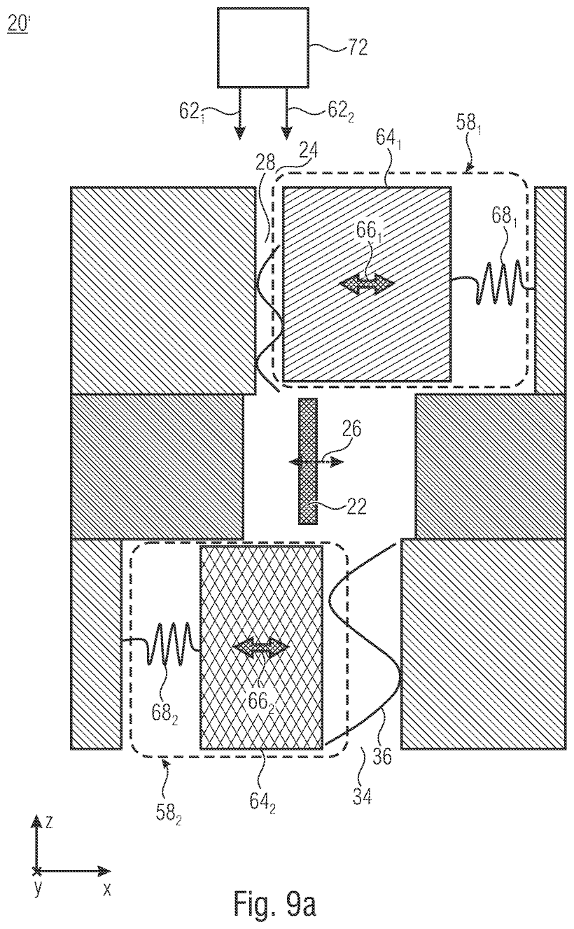

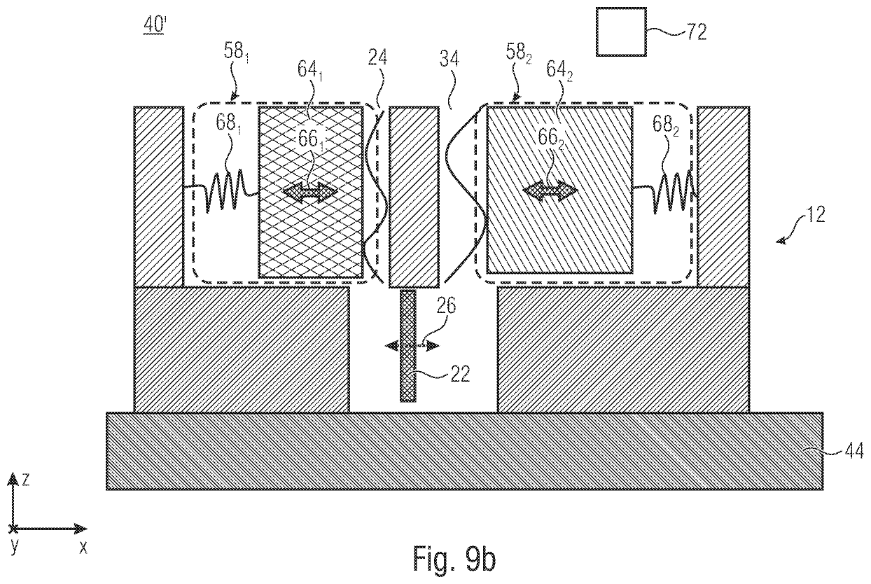

FIG. 9a shows a schematic cross-sectional view of an MEMS 20′ which, when compared to the MEMS 20, comprises a phase matcher.

In accordance with an embodiment, the MEMS 20′ may comprise a phase matcher 58₁ for matching a phase shift for the periodic oscillation 28 and/or may comprise a phase matcher 58₂ for matching a phase shift for the periodic oscillation 36 by the opening 34. Exemplarily, the phase matcher 58₁ may receive a drive signal 62₁ and adjust the phase shift of the opening 24 based thereon. Alternatively or additionally, the phase matcher 58₂ may be configured to receive a drive signal 62₂ and adjust the phase offset of the opening 34 based thereon. The phase matchers 58₁ and 58₂ may each be arranged independently and may also be arranged as a common phase matcher. For example, the phase matcher 58₁ may comprise a moveable structure 64₁ and/or the phase matcher 58₂ may comprise a moveable structure 64₂ which may be arranged to be moveable along one or more directions of movement in order to adjust the phase shift based on a movement obtained by this. Exemplarily, phase matchers may be configured, as is the case in embodiments described herein, to change a size of the opening 24 and/or a size of the opening 34 to adjust the phase offset. Alternatively or additionally, the phase matcher can be configured to change a temperature and/or a fluid density of the like locally in the region of the opening 24 to adjust the phase offset. Possibly, the phase matcher 58₁ comprises an actuator 68₁ to move the element 64₁ and/or to generate other effects. The phase matcher 58₂ may comprise an actuator 68₂.

In other words, FIG. 9a shows the extension of the arrangement in FIG. 2 where the geometrical dimensions of the air outlet opening can be changed by additional actuators in the lid and/or bottom wafer. Thus, the directional characteristic can be controlled actively without the displacing elements having to receive another signal, that means the moveable element can be driven in a potentially unamended manner. Furthermore, main lobes are possible in this way (array principle) which can be changed actively by displacing the air outlet openings. Additionally, by changing the geometry, the phase correction/phase matching can be realized for a wide wavelength range, which can increase the frequency bandwidth of the device relative to a static implementation considerably.

FIG. 9b shows a schematic side sectional view of an MEMS 40′ which is extended, when compared to the MEMS 40, by providing a phase matcher 58₁ and a phase matcher 58₂. The phase matcher 58₁ and/or 58₂ may thus be implemented independently, for example only one of these may be implemented. Each of the phase matchers 58₁ and 58₂ may alternatively or additionally be implemented as is explained in FIG. 9a.

In other words, FIG. 9b shows the extension of the arrangement in FIG. 4 where the geometrical dimensions of the air outlet openings can be changed by means of additional actuators in the lid wafer. Thus, transducers with no back volume and an actively controllable direction of the main lobe are possible.

A phase matcher as described herein may be realized individually in an MEMS as described herein, but also in an array. In an array, a controller illustrated in FIGS. 9a and 9b can be configured to provide the match signals 62₁ and 62₂. Even when a single MEMS may be configured to receive a drive signal 62₁ and 62₂ from externally, it may be of advantage for the entire array to have already integrated the controller even though this is not necessary. The phase matcher of an array may be configured to receive the at least one drive signal and to adjust at least a first phase offset of one of the openings 24 and/or at least one phase offset of the openings 34 based on the drive signal. The more openings are implemented for adjusting a phase offset, the higher will the degree of freedom which can be obtained be. In accordance with an embodiment, the controller is configured to control the phase offset of the at least one opening 34 independently of a phase offset of the at least one opening 24 and/or the phase offset of the at least one opening 24 independently of a phase offset of the at least one opening 34.

In accordance with an embodiment, the controller 72 is configured to control the phase matcher based on the drive signal to generate, for superpositioning of the phase-offset first periodic oscillations 32 and/or for superpositioning of the phase-offset second periodic oscillations 36, at least one among a change of a lobe of a directional characteristic of the superpositioning, compensation for a broad-band phase matching and modulation of a signal onto a frequency of the first and/or second phase-offset periodic oscillations. The compensation of broad-band phase matching can be employed for frequency-precisely tracking the phase matching. For example, for a chirp signal, which is frequently used, the phase matching can be tracked ideally. This may, for example, be done such that the phase offset will always be exactly 180° for the current frequency of the periodic oscillation generated.

In accordance with an embodiment, an apparatus as described herein comprises an MEMS in accordance with an embodiment and/or an array in accordance with an embodiment. As has been discussed in connection with embodiments described herein, the different openings 24 and 34 of an MEMS may be connected to the same fluidic volume. Optionally, the MEMS may be configured to be a loudspeaker. This allows implementing the loudspeaker optionally without a separate back volume.

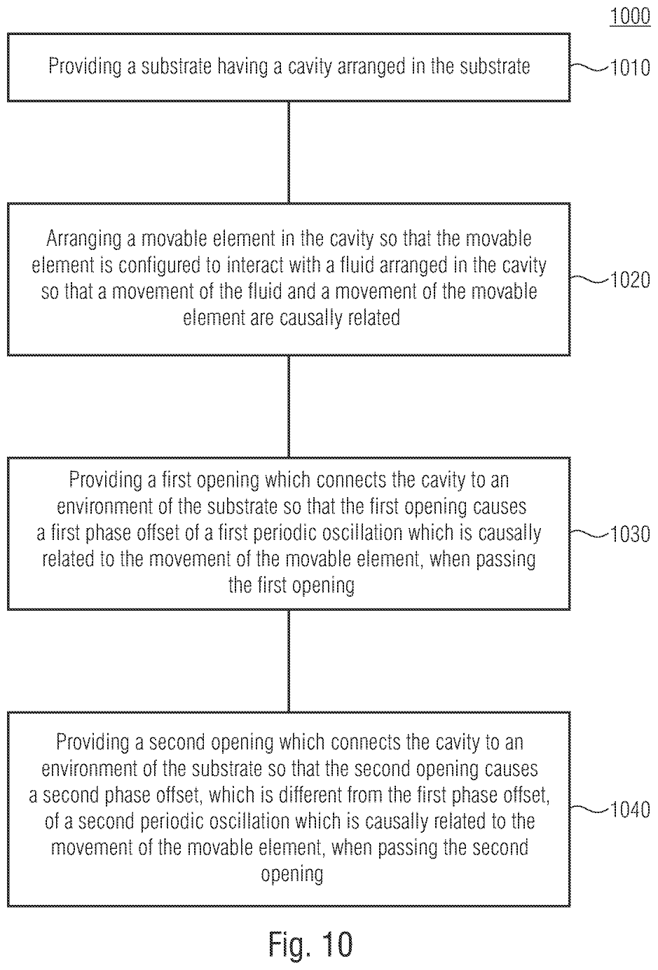

FIG. 10 shows a schematic flow chart of a method 1000 in accordance with an embodiment, used exemplarily for producing an MEMS as described herein. Step 1010 comprises providing a substrate having a cavity arranged in the substrate.

Step 1020 comprises arranging a movable element in the cavity so that the movable element is configured to interact with a fluid arranged in the cavity so that a movement of the fluid and a movement of the movable element are causally related.

Step 1030 comprises providing a first opening which connects the cavity to an environment of the substrate so that the first opening causes a first phase offset of a first periodic oscillation which is causally related to the movement of the moveable element, when passing through the first opening. Step 1040 comprises providing a second opening which connects the cavity to the environment of the substrate such that the second opening causes a second phase offset, different from the first phase offset, of a second periodic oscillation which is causally related to the movement of the movable element, when passing through the second opening.

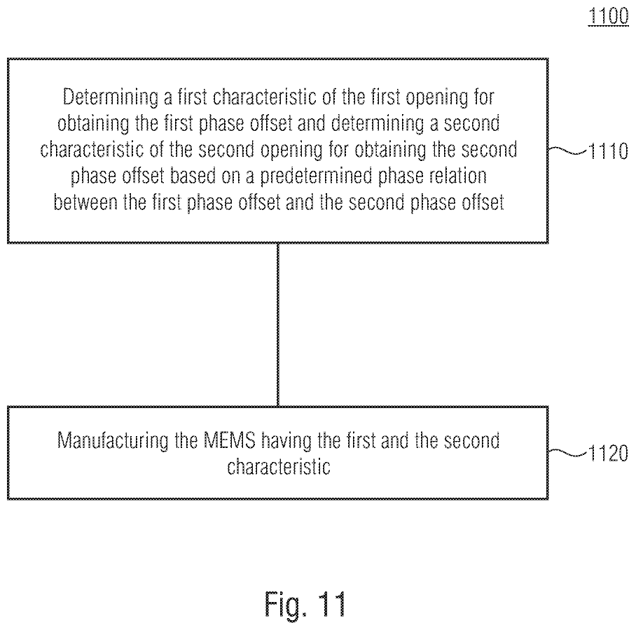

FIG. 11 shows a schematic flow chart of a method 1100 in accordance with an embodiment which can be used, for example, for configuring or dimensioning an MEMS as described herein. The method 1100 may, for example, but not necessarily, be configured to be computer-implemented.

Step 1110 comprises determining a first characteristic of the first opening for obtaining the first phase offset and determining a second characteristic of a second opening for obtaining the second phase offset based on a predetermined phase relation between the first phase offset and the second phase offset.

Step 1120 comprises manufacturing the MEMS having the first characteristic and the second characteristic.

Embodiments described herein provide MEMS devices and arrays and apparatus comprising these wherein the MEMS devices may comprise layer stacks which include at least one substrate layer in which the electrodes and the passive elements are arranged. Further layers relate to a bottom, also referred to as handling wafer, and a lid, also referred to as lid wafer. Both lid and handling wafers can be firmly connected to the substrate plane, advantageously by bonding, thus resulting in acoustically encapsulated intermediate gaps in devices. In this gap, which corresponds to the device plane, the deformable devices can deform, in other words deformation takes place in-plane.

The layers may, for example, comprise electrically-conductive materials, like doped semi-conductor materials and/or metal materials, for example. The layer arrangement of electrically-conductive layers allows an easy implementation since electrodes (for deflectable elements) and passive elements can be formed by selectively being dissolved from the layer. In case electrically non-conductive materials are to be arranged, this may be implemented by depositing these materials layer by layer.

Embodiments described herein achieve the object of providing or striving for an apparatus for effectively displacing a volume flow in the ultrasonic range (acoustic wave, periodic oscillation) at a minimum space consumption and maximum power efficiency. The transducer may comprise a wafer stack having a device and a lid wafer. Additionally, a bottom wafer may also be present. The device wafer may comprise a displacing element, having a first and a second displacing direction, like in the sense of an acoustic dipole. The first and the second outlet openings may be connected to the environment. By means of different geometries and, maybe, the position of the first and second air outlet opening, the phase offset between the exiting waves can be changed or adjusted. This allows achieving a desired setting of the directional characteristic of the entire transducer.

In order to avoid a back volume and guide the energy from the backside to the front, the sound guiding can be implemented such that both air outlet openings terminate at the front. It is of advantage here to implement the sound guiding such that the two sound waves exit at the surface of the transducer advantageously in-phase or at a defined phase offset. The phase offset is advantageously produced by the acoustic effects in the narrow air outlet channels, wherein the phase offset of the first and second displacing sides can be adjusted by the different path lengths, positions, shapes or widths of the two air outlet openings relative to each other. In a typical chip stack, however, the Bosch process can prevent etching the outlet openings, which here act as wave guides, to such a depth that a meandering phase offset, for example, would result. Alternatively, thermoviscous effects in the narrow channels may be used advantageously, wherein, in the case of different thicknesses of the first and second air outlet openings, a phase offset can be generated due to the strongly varying acoustic characteristic up to reaching the chip surface.

An advantageous design of the opening provides for the phase of the sound to rotate by 180° from the front to the backside of the actuator within the chip until reaching the surface, wherein the summed-up power of the first and second displacing sides on a chip side is obtained. Thus, a back volume is no longer required.

Embodiments of the present invention relate to hardware and apparatus. An apparatus for displacing the air for generating sound waves having a geometrically adjusted shape and position of the air outlet openings can be provided, which serves for shaping the directional characteristic. Phase-different sides of an emitting element can be used and the openings may comprise a corresponding position relative to the emitting element, like relative to the chamber volume at a time of positive pressure sign, and vice versa.

The following aspects are addressed by embodiments described herein:
1. different phase shift in the case of different air outlet openings
2. phase offset by thermoviscous effects
   2.1 by varying the geometrical shape and position of the air outlet openings
   2.2 designing allows a defined phase offset between the two exit openings
3. two air outlets belonging to a displacer on one side of the chip
   3.1 displacing elements having a first and a second displacing side
   3.2 sound guiding of the two displacing sides is different
4. phase offset such that the phase at the output is equal in all the outlets belonging to the beam
   4.1 back volume can be omitted completely
5. Phase offset such that the phase controls the propagation direction of the wave in the outlets belonging to a beam
   5.1 directional characteristic of the transducer can be designed
   5.2 non-perpendicular main lobes possible (array principle)
6. phase offset such that the phase controls the propagation direction of the wave in the outlets belonging to several beams
   6.1 several possibilities for angle design
7. phase offset and position of the outlets such that the wave propagation direction on both sides of the chip is controlled independently
8. active phase change at the outlet by active change of the geometrical shape of the outlet opening
   8.1 active control of the geometry of the outlet openings
   8.2 active control of the angle of the main lobe, active beam steering
   8.3 compensation for broad-band phase matching
   8.4 modulation of signals onto the carrier frequency
9. phase offset such that the wave is focused over the chip surface onto one or more points
10. using AVT (chip on board) for being used as a back/second outlet/inlet
   10.1 outlet openings may also be formed at the back by the implementation and connection technique
   10.2 can also be designed relative to the phase offset. This also allows implementing space savings (no backside wafer)
11. setting a phase offset via the setup and connection technique (AVT), maybe special carrier board (grooves, holes, glue)
   11.1 the carrier board may comprise special adjustments, for example grooves and holes for each displacing chamber
   11.2 the glue for connecting chip and carrier board is used for channel shaping (for example filling material for setting a channel height)
12. further setting of the phase offset by varying the shape of the air outlet opening in the wave propagation direction
   12.1 one or more steps, for example by etching
   12.2 oblique walls
   12.3 non-straight walls, like scallops or curved walls, for example

Although some aspects have been described within the context of an apparatus, it is understood that said aspects also represent a description of the corresponding method, so that a block or a structural component of an apparatus is also to be understood to be a corresponding method step or feature of a method step. In analogy, aspects described within the context of or as a method step also represent a description of a corresponding block or detail or feature of a corresponding apparatus.

Depending on specific implementation requirements, embodiments of the invention may be implemented in hardware or in software. Implementation may be effected while using a digital storage medium, for example a floppy disc, a DVD, a Blu-ray disc, a CD, a ROM, a PROM, an EPROM, an EEPROM or a FLASH memory, a hard disc or any other magnetic or optical memory which has electronically readable control signals stored thereon which may cooperate, or cooperate, with a programmable computer system such that the respective method is performed. This is why the digital storage medium may be computer-readable. Some embodiments in accordance with the invention thus comprise a data carrier which comprises electronically readable control signals capable of cooperating with a programmable computer system such that any of the methods described herein is performed.

Generally, embodiments of the present invention may be implemented as a computer program product having program code, the program code being effective to perform any of the methods when the computer program product runs on a computer. The program code may also be stored on a machine-readable carrier, for example.

Other embodiments include the computer program for performing any of the methods described herein, said computer program being stored on a machine-readable carrier.

In other words, an embodiment of the inventive method thus is a computer program which has program code for performing any of the methods described herein, when the computer program runs on a computer. A further embodiment of the inventive methods thus is a data carrier (or a digital storage medium or a computer-readable medium) on which the computer program for performing any of the methods described herein is recorded.

A further embodiment of the inventive method thus is a data stream or a sequence of signals representing the computer program for performing any of the methods described herein. The data stream or the sequence of signals may be configured, for example, to be transferred via a data communication link, for example via the internet.

A further embodiment includes processing means, for example a computer or a programmable logic device, configured or adapted to perform any of the methods described herein.

A further embodiment includes a computer on which the computer program for performing any of the methods described herein is installed.

In some embodiments, a programmable logic device (for example a field-programmable gate array, FPGA) may be used for performing some or all of the functionalities of the methods described herein. In some embodiments, a field-programmable gate array may cooperate with a microprocessor to perform any of the methods described herein. Generally, the methods are performed, in some embodiments, by any hardware device. Said hardware device may be any universally applicable hardware such as a computer processor (CPU), or may be a hardware specific to the method, such as an ASIC.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

1. An MEMS comprising:
a substrate;
a cavity arranged in the substrate;
at least one movable element arranged in the cavity, configured to interact with a fluid arranged in the cavity, wherein a movement of the fluid and a movement of the movable element are causally related;
a first opening which connects the cavity to an environment of the substrate and which causes a first phase offset of a first periodic oscillation which is causally related to the movement of the movable element when passing through the first opening;
a second opening which connects the cavity to the environment of the substrate and which causes a second phase offset, different from the first phase offset, of a second periodic oscillation which is causally related to the movement of the movable element when passing through the second opening.

2. The MEMS in accordance with claim 1, wherein the movable element is arranged to be movable in-plane in a plane in parallel to a substrate plane of the substrate.

3. The MEMS in accordance with claim 1, configured to provide the first phase offset and the second phase offset based on a thermoviscous effect.

4. The MEMS in accordance with claim 1 wherein the first opening differs from the second opening in at least one among:
an opening cross-section of the opening;
a shape of the opening cross-section along a direction through the substrate; and
a depth in the substrate;
to generate a mutually different phase offset.

5. The MEMS in accordance with claim 1, wherein the first opening and the second opening are configured to output the first periodic oscillation with the first phase offset and the second periodic oscillation with the second phase offset into a common volume in which the first periodic oscillation and the second periodic oscillation superimpose each other.

6. The MEMS in accordance with claim 1, wherein superpositioning of the first periodic oscillation and the second periodic oscillation is free from acoustic short-circuiting.

7. The MEMS in accordance with claim 1, wherein the first opening and the second opening are arranged on a same side of the substrate.

8. The MEMS in accordance with claim 1, wherein the movable element comprises a first side and an opposite second side, wherein the movable element is configured to produce the first periodic oscillation with a displacement of the fluid by the first side, associated with the movement of the movable element, and to move the fluid through the first opening; and to produce the second periodic oscillation with a displacement of the fluid by the second side, associated with the movement of the movable element, and to move the fluid through the second opening.

9. The MEMS in accordance with claim 8, wherein sound guiding through the first opening by the first side is different from sound guiding through the second opening by the second side, based on the first phase offset and the second phase offset.

10. The MEMS in accordance with claim 1, wherein the first phase offset comprises a first correlation to the movement of the movable element; and the second phase offset comprises a second correlation to the movement of the movable element; wherein the first phase offset and the second phase offset comprise a mutual relation to output the first periodic oscillation with the first phase offset and the second periodic oscillation with the second phase offset to the environment with phase matching within a tolerance range.

11. The MEMS in accordance with claim 1, wherein the first phase offset comprises a first correlation to the movement of the movable element; and the second phase offset comprises a second correlation to the movement of the movable element; wherein the first phase offset and the second phase offset comprise a mutual relation to output the first periodic oscillation with the first phase offset and the second periodic oscillation with the second phase offset to the environment with a directional characteristic acquired by superpositioning the first periodic oscillation and the second periodic oscillation.

12. The MEMS in accordance with claim 11, wherein the directional characteristic is arranged obliquely relative to a surface normal of the substrate and a direction of the first opening and/or the second opening.

13. The MEMS in accordance with claim 1, comprising a phase matcher configured to receive a drive signal and to adjust the first phase offset and/or the second phase offset based on the control signal.

14. The MEMS in accordance with claim 13, wherein the phase matcher is configured to change a size of the first opening to adjust the first phase offset; and/or to change a size of the second opening to adjust the second phase offset.

15. The MEMS in accordance with claim 1, wherein the first periodic oscillation comprises a first sound wave, a first ultrasonic wave and/or a first acoustic wave; and/or wherein the second periodic oscillation comprises a second sound wave, a second ultrasonic wave and/or a second acoustic wave.

16. The MEMS in accordance with claim 1, wherein the movable element is configured to generate, with the movement, the first periodic oscillation and the second periodic oscillation at different phases.

17. An array comprising a plurality of MEMS in accordance with claim 1.

18. The array in accordance with claim 17, configured to emit the first phase-offset periodic oscillations with a common directional characteristic and/or to emit the second phase-offset periodic oscillations with a common directional characteristic.

19. The array in accordance with claim 18, configured to emit the first phase-offset periodic oscillations with a common directional characteristic, which is arranged obliquely relative to a surface normal of the substrate and a direction of the first openings of the plurality of MEMS, and wherein the first openings of the plurality of MEMS are implemented for a mutually different phase offset; and/or
configured to emit the second phase-offset periodic oscillations with a common directional characteristic, which is arranged obliquely relative to a surface normal of the substrate and a direction of the second openings of the plurality of MEMS, and wherein the second openings of the plurality of MEMS are implemented for a mutually different phase offset.

20. The array in accordance with claim 17, wherein the plurality of first openings provide a respective phase offset of the first periodic oscillations and superpositioning of the phase-offset first periodic oscillations is directed to a common first focus region; and/or wherein the plurality of second openings provide a respective phase offset of the second periodic oscillations and superpositioning of phase-offset second periodic oscillations is directed to a common second focus region.

21. The array in accordance with claim 20, wherein the first focus region and the second focus region are spatially adjacent or overlapping.

22. The array in accordance with claim 17, comprising a controller configured to provide a drive signal; and
a phase matcher configured to receive the drive signal and to adjust at least a first phase offset of at least one of the first openings and/or at least a second phase offset of at least one of the second openings based on the drive signal.

23. The array in accordance with claim 22, wherein the controller is configured to control the phase offset of the at least one of the second openings irrespective of a phase offset of the at least one of the first openings and/or to control the phase offset of the at least one of the first openings irrespective of a phase offset of the at least one of the second openings.

24. The array in accordance with claim 22, wherein the controller is configured to control the phase matcher based on the drive signal, to generate, for superpositioning of the phase-offset first periodic oscillations and/or for superpositioning of the phase-offset second periodic oscillations, at least one among:
a change in a lobe of a directional characteristic of superpositioning;
a compensation for broad-band phase matching
a modulation of a signal onto a frequency of the first and/or second phase-offset periodic oscillations.

25. An apparatus comprising:
an MEMS in accordance with claim 1; or
an array comprising a plurality of MEMS in accordance with claim 1,
wherein the first opening and the second opening of the MEMS are connected to the same fluidic volume.

26. The apparatus in accordance with claim 25, wherein the MEMS is configured to be a loudspeaker and is configured not to comprise a back volume.

27. The apparatus in accordance with claim 25, configured for superpositioning of the first periodic oscillation and the second periodic oscillation in a common volume, wherein superpositioning is free from any acoustic short-circuiting.

28. A method of producing an MEMS, comprising:
providing a substrate comprising a cavity arranged in the substrate;
arranging at least one movable element in the cavity so that the movable element is configured to interact with a fluid arranged in the cavity so that a movement of the fluid and a movement of the movable element are causally related;
providing a first opening which connects the cavity to an environment of the substrate so that the first opening causes a first phase offset of a first periodic oscillation which is causally related to the movement of the movable element when passing through the first opening; and
providing a second opening which connects the cavity to the environment of the substrate so that the second opening causes a second phase offset, which is different from the first phase offset, of a second periodic oscillation which is causally related to the movement of the movable element when passing through the second opening.

29. A method of configuring an MEMS in accordance with claim 1, comprising:
determining a first characteristic of the first opening for acquiring the first phase offset and determining a second characteristic of the second opening for acquiring the second phase offset based on a predetermined phase relation between the first phase offset and the second phase offset; and
manufacturing the MEMS comprising the first and the second characteristic.
